(19) United States
(12) Patent Application Publication
(10) Pub. No.: US 2023/0245868 A1
(43) Pub. Date: Aug. 3, 2023

(54) HOLDING DEVICE, AND USE OF THE HOLDING DEVICE

(71) Applicant: HANWHA Q CELLS GMBH, Bitterfeld-Wolfen (DE)

(72) Inventor: Martin SCHAPER, Bitterfeld-Wolfen (DE)

(21) Appl. No.: 17/998,541

(22) PCT Filed: May 7, 2021
(86) PCT No.: PCT/DE2021/100418

§ 371 Date: Nov. 11, 2022

(30) Foreign Application Priority Data
May 11, 2020 (DE) 10 2020 112 641.7

(51) Int. Cl. H01J 37/32; H01L 21/673; C23C 16/46; C23C 16/458

(52) U.S. Cl. CPC H01J 37/32724; C23C 16/463; C23C 16/4583; H01L 21/6733; H01L 21/67316; H01J 2237/002; H01J 2237/026; H01J 2237/201; H01J 2237/3321

(57) ABSTRACT

A holding device for holding a plurality of substrates for plasma-enhanced deposition of a layer from the gas phase on the substrates, having: inner carrier plates, arranged parallel to one another and designed to carry substrates on mutually opposite sides; outer carrier plates, arranged parallel to the inner carrier plates and having an inner side facing the inner carrier plates, and an outer side facing away from the inner carrier plates, wherein each outer carrier plate is designed to carry one or more substrates on its inner side and to be free of substrates on its outer side; and shielding plates which are each arranged at a distance from the outer side of the outer carrier plate such that, as seen in a plan view of the outer carrier plates, the shielding plates at least predominantly shield the outer carrier plates, wherein each shielding plate is free of substrates.

### RELATED APPLICATIONS

The present application is a National Phase entry of PCT Application No. PCT/DE2021/100418, filed May 7, 2021, which claims priority to German Patent Application No. 10 2020 112 641.7, filed May 11, 2020, the disclosures of which are hereby incorporated by reference herein in their entirety.

### FIELD OF THE INVENTION

The invention relates to a holding apparatus and to a use of the holding apparatus. In particular the invention relates to a holding apparatus for holding a substrate in a plasma-assisted deposition of a layer from the gas phase onto the substrate and to a use of such a holding apparatus.

### BACKGROUND OF THE INVENTION

DE102015004430A1 discloses a holding apparatus for holding a plurality of substrates in a plasma-assisted deposition of a layer from the gas phase onto the substrate. The holding apparatus comprises carrier inner plates arranged parallel to one another which are each configured for carrying substrates on opposite sides. It further comprises carrier outer plates arranged parallel to the carrier inner plates having an inner surface facing the carrier inner plates and an outer surface facing away from the carrier inner plates. Each carrier outer plate is configured for carrying one or more substrates on its inner surface and to be substrate-free on its outer surface.

The carrier inner plates and carrier outer plates each comprise a suitable holding means such as for example substrate pockets, holding pins or the like to hold the substrates, wherein individual substrates in the holding apparatus must be kept at a predetermined distance from one another to allow the most uniform possible passage of gases through all intermediate spaces and the formation of a plasma between the substrates. This ensures uniform coating of the substrates.

The holding apparatus, also referred to in the technical jargon as a boat, is in particular used for securely accommodating as many substrates as possible for the manufacture of solar cells to allow handling and processing of a holding apparatus loaded with substrates without the risk of damaging the substrates.

To effect coating of the substrates in a chemical gas phase deposition such as for example a PECVD process they are initially arranged on the carrier plates of the holding apparatus and then the holding apparatus is arranged in a chemical deposition apparatus such as for example a heatable tube of a PECVD plant. In the deposition/coating process a layer is deposited on the substrates present in the holding apparatus. However, before coating the holding apparatus present in the chemical vapor deposition apparatus is initially heated to a predetermined process temperature which depends on the layer to be produced on the substrates. The heating is preferably effected via thermal radiation acting in the direction of the holding apparatus from an external source. However, the inner carrier plates and the outer carrier plates undergo heating at different rates. However, the temperature differences in the region of different carrier plates result in nonuniform results in layer deposition, thus resulting in unwanted efficiency losses.

Especially in multilayered deposition such as for example in the case of deposition of AlOx (aluminium oxide) and SiNx (silicon nitride) onto the substrates different process temperatures are required, thus requiring the temperature to be altered during the process. Any temperature differences occurring in the region of different carrier plates are disadvantageous.

### SUMMARY

It is accordingly an object of the present invention to provide a holding apparatus which realizes a more uniform temperature distribution in the region of the carrier inner plates and carrier outer plates to realize more homogeneous results in thin layer production in chemical vapor deposition processes.

According to the invention this object is achieved by a holding apparatus having the features of claim 1 and the use of a holding apparatus having the features of claim 9. Advantageous developments and modifications are specified in the dependent claims.

According to the invention the holding apparatus further comprises shielding plates which are arranged in each case spaced apart from the outer surface of the carrier outer plate such that the shielding plates at least very largely shade the carrier outer plates in a plan view of the carrier outer plates, wherein each shielding plate is configured to be substrate-free.

The invention is based on the basic concept that in prior art holding apparatuses thermal radiation incident on the holding apparatus during the deposition process directly impacts the carrier outer plates of the holding apparatus. However, the carrier inner plates arranged between the two carrier outer plates are shaded by the carrier outer plates. This has the result that the carrier outer plates undergo markedly faster heating than the carrier inner plates. To ensure that the holding apparatus has the same temperature in the region of all of its carrier outer plates and carrier inner plates a certain amount of time must be allowed to elapse. The same applies to cooling during a process or during transition from one process to the next. If the surroundings of the holding apparatus are the heat sink it takes longer for the carrier inner plates to cool than the carrier outer plates. Either a certain temperature gradient over the spatial distribution of the carrier and inner plates is accepted or it is necessary to wait for an appropriate length of time until the desired thermal equilibrium has been established.

A waiting time that is too short frequently results in temperature-dependant inhomogeneities during layer deposition on the substrates. For these reasons the shielding plates are arranged in the function of a heat shield. The arrangement is effected such that direct incidence of thermal radiation from component elements of the deposition apparatus surrounding the holding apparatus onto the carrier outer plates is very largely blocked. The shielding plates likewise reduce the cooling rate of the carrier outer plates. This has the result that the dynamic temperature profile of the carrier outer plates approximates that of the carrier inner plates so that all substrate-carrying carrier plates have an ideally identical or at least sufficiently similar temperature profile.

The wording “the shielding plates at least very largely shade the carrier outer plates in a plan view of the carrier outer plates” is to be understood as meaning that in a perpendicular plan view of the carrier outer plates the shielding plates effect geometric shading of > 50%, preferably >70%, more preferably > 90 %, yet more preferably 100%, of the area of the carrier outer plates.

The term “substrate-free” is to be understood as meaning that such a substrate-free plate is structurally configured not to carry a substrate during the deposition process. A plate configured for carrying a substrate comprises for example a holding means such as for example structural elements such as substrate pockets, holding pins or the like to secure the substrates.

The holding apparatus is in particular configured as a boat for a chemical vapor deposition apparatus, preferably PECVD deposition apparatus, more preferably a tubular PECVD plant. The holding apparatus in particular comprises two carrier outer plates and in each case an, i.e. altogether two, associated shielding plates.

In a preferred embodiment the shielding plates and the carrier outer plates and the carrier inner plates are flat and arranged substantially parallel to one another. The term “flat” is to be understood as meaning a flat, preferably planar, continuous structure. However, the structure may also have in-plane openings.

Alternatively or in addition the shielding plates are preferably arranged in each case in parallel spaced apart from the outer surface of the carrier outer plate. The carrier inner plates and the carrier outer plates are preferably all connected to one another via one or more rods and are therefore spaced apart from one another at a predetermined distance. For example the carrier inner plates and the carrier outer plates are spaced apart from one another using spacers which encapsulate sections of the rod(s). The shielding plates too may be connected to the carrier inner and outer plates via these one or more rods and are therefore spaced apart from the carrier outer plates at a further predetermined distance to the carrier outer plates, wherein the predetermined distance and the further predetermined distance may be identical or different. However, the shielding plates may also be mounted to the holding apparatus via other joining means.

In a preferred embodiment length and/or width measurements of the shielding plates are smaller than length and/or width measurements of the carrier outer plates. This ensures that the holding apparatus optimally utilizes the space in the chemical deposition apparatus.

The carrier inner plates and the carrier outer plates are insulated relative to one another and alternatingly connected to connections of an alternating voltage generator, at least when in the chemical deposition apparatus, in order that a plasma is produced during performance of a deposition process. The shielding plates are preferably free from an electrical contact and also not connected to a connection of an alternating voltage generator when using the holding apparatus in the chemical deposition apparatus. It is alternatively preferable when the shielding plates have an electrical contact and are connected to the connection of an alternating voltage generator. They preferably have the same polarity as the immediately adjacent carrier outer plates.

In a further preferred embodiment each shielding plate comprises a cooling means. This is a simple way to influence the temperature kinetics of the shielding plate and thus indirectly also the adjacent carrier outer plates.

The cooling means is preferably in the form of a rib-like and/or wave-shaped surface structure of each shielding plate. The surface structure thus comprises elevations similar to a rib and/or a wave to enlarge the surface area of the shielding plate. This is an easy-to-implement cooling means which makes it possible to influence the temperature kinetics of the shielding plate.

The shielding plates may be single-layered or multi-layered. They are preferably multi-layered This further improves the shielding.

In a preferred embodiment the shielding plates are made of a base material selected from the group of graphite, carbon fiber-reinforced plastic or carbon fiber-reinforced carbon. Carbides, quartz or ceramics can also be used as the base material.

The base material may be uncoated. However, the base material may also be provided with a coating. The coating is preferably selected such that it is a good reflector of infrared radiation, while the base material is then preferably selected such that, even when hot, it ideally radiates less infrared radiation than the coating.

Outer surfaces of the shielding plates are preferably provided with a coating in the form of a metal layer. This further and choose the good thermal reflection of the outer surfaces of the shielding plates is realized. The metal layer is preferably in the form of a corrosion-resistant noble metal layer. The noble metal layer is a gold or platinum layer for example. The outer surfaces of the shielding plates may be provided with the layer over some or all of their area. They are preferably provided with a layer over all of their area.

The carrier inner plates and the carrier outer plates are preferably made of a material selected from the group of graphite, carbon fiber-reinforced plastic or carbon fiber-reinforced carbon. The material may be uncoated or coated.

The carrier inner plates and the carrier outer plates preferably comprise cutouts in which the substrates may be accommodated. For example, the carrier inner plates and the carrier outer plates each have one or more substrate pockets. These serve as a holding means for the substrates. The carrier inner plates and the carrier outer plates may further each comprise holding pins to hold the substrates.

The shielding plates too may comprise cutouts, openings or holes. However, it must be ensured that the holes and openings have dimensions such that the desired extent of thermal shielding is achieved.

In a preferred embodiment the shielding plates are free from cutouts, openings and holes. That is to say they comprise no depressions, openings or holes. This ensures high shielding.

The invention further relates to a use of the holding apparatus according to one or more of the above-described embodiments in a plasma-assisted deposition from the gas phase as a holding apparatus for substrates, in particular solar cells processed out of semiconductor wafers.

The use according to the invention provides that a holding apparatus configured as a boat for vapor deposition plants is used as a holding apparatus for substrates in a plasma-assisted deposition from the gas phase. This allows the substrates to be coated particularly homogeneously and easily. The duration of coating processes in which a temperature profile over time must be completed is reduced since due to the shielding plates the temperature kinetics of carrier outer plates versus carrier inner plates are approximately equal during heating and during cooling.

The holding apparatus is therefore used especially in all chemical vapor deposition processes having a limited time for temperature stabilization. The holding apparatus is preferably used in all deposition processes which employ a tubular PECVD plant and particularly preferably in deposition processes where two or more layers are successively deposited in the same deposition plant at different process temperatures.

The substrates are wafers for example. The substrates are preferably silicon substrates and more preferably silicon solar cell substrates. The plasma-assisted deposition from the gas phase is preferably a CVD (Chemical Vapor Deposition) or PECVD (Plasma Enhanced Chemical Vapor Deposition) process.

The holding apparatus is preferably used in a deposition where silicon, silicon nitride or silicon oxynitride, silicon carbide and/or aluminum oxide are deposited on the substrates from the gas phase. The deposited layers may be electrically conductive layers where the aforementioned layers are doped.

### BRIEF DESCRIPTION OF THE DRAWINGS

Further properties and advantages of the invention will be clearly described below by way of example in conjunction with the embodiment shown in the figure. In the figures which are schematic and not to scale:

FIG. 1 shows a sectional view of a process chamber of a chemical deposition apparatus in which a holding apparatus according to the invention is arranged.

### DETAILED DESCRIPTION

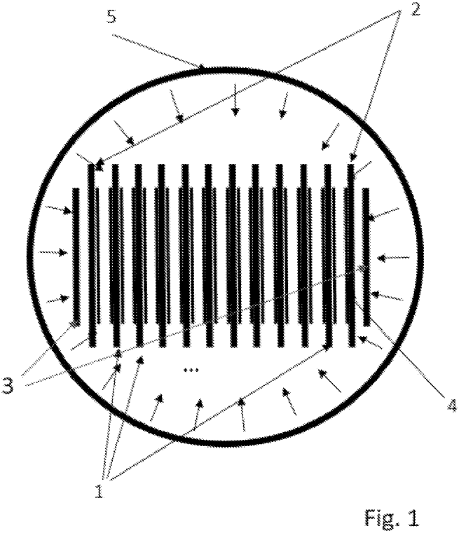

FIG. 1 shows a sectional view of a process chamber of a chemical deposition device in which a holding apparatus according to the invention is arranged. The holding apparatus according to the invention is arranged in a process chamber 5 of a tubular PECVD deposition apparatus.

The holding apparatus comprises a plurality of carrier inner plates 1 arranged parallel to one another. Each carrier inner plate 1 is configured to carry one or more substrates 4 on opposite sides. The holding apparatus further comprises two carrier outer plates 2 arranged parallel to the carrier inner plates 1, each having an inner surface facing the carrier inner plates 1 and an outer surface facing away from the carrier inner plates 1. Each carrier outer plate 2 is configured to carry one or more substrates 4 on its inner surface and to be substrate-free on its outer surface, so that it has no substrate on its outer surface during deposition of layers. The carrier inner plates 1 and the carrier outer plates 2 are connected to one another via one or more rods (not shown) and spaced apart from one another at a predetermined distance via spacers (likewise not shown).

The holding apparatus further comprises two shielding plates 3 which are arranged in each case spaced apart from the outer surface of the carrier outer plate 2 such that the shielding plates 3 at least very largely shade the carrier outer plates 2 in a plan view of the carrier outer plates 2. Each shielding plate 3 is configured to be substrate-free, i.e. said plates do not comprise any structures allowing securing of a substrate or a plurality of substrates.

The holding apparatus is arranged in the process chamber 5 to deposit on the substrates 4 one or more layers by chemical gas phase reaction. To this end the process chamber 5 is heated via a heating apparatus (not shown), as a result of which the heating apparatus including the substrate 4 and the wall of the tubular process chamber 5 are likewise heated. The wall of the process chamber 5 radiates heat, as indicated by the short arrows emanating from the wall of the process chamber. The shielding plates 3 very largely shield the outer carrier plates 2 from the thermal radiation which is emitted from the wall of the process chamber 5 in the direction of the outer carrier plates 2. As a result, a portion of the thermal radiation from the wall of the process chamber 5 acts predominantly on the shielding plates 3 initially and on the carrier outer plates 2 only subsequently, wherein the remaining portion of the thermal radiation from the wall of the process chamber is incident on the carrier inner plates 1 and the carrier outer plates 2. In the case of temperature kinetics of the shielding plate optimized for the specific deposition process a substantially similar temperature profile for the carrier outer plates versus the carrier inner plates can be realized.

List of reference numerals

| | |
|---|---|
| 1 | carrier inner plates |
| 2 | carrier outer panels |
| 3 | shielding plates |
| 4 | substrate |
| 5 | process chamber |

1. A holding apparatus for holding a plurality of substrates in a plasma-assisted deposition of a layer from a gas phase onto the substrate, comprising:
carrier inner plates arranged parallel to one another which are each configured for carrying substrates on opposite sides,
carrier outer plates arranged parallel to the carrier inner plates having an inner surface facing the carrier inner plates and an outer surface facing away from the carrier inner plates, wherein each carrier outer plate is configured for carrying one or more substrates on its inner surface and to be substrate-free on its outer surface, and
shielding plates which are arranged in each case spaced apart from the outside of the carrier outer plate such that the shielding plates shade the carrier outer plates in a plan view of the carrier outer plates, wherein each shielding plate is configured to be substrate-free.

2. The holding apparatus as claimed in claim 1, wherein the shielding plates and the carrier outer plates and the carrier inner plates are flat and arranged substantially parallel to one another and/or in that the shielding plates are arranged in each case in parallel spaced apart from the outer surface of the carrier outer plate.

3. The holding apparatus as claimed in claim 1, wherein length and/or width measurements of the shielding plates are smaller than length and/or width measurements of the carrier outer plates.

4. The holding apparatus as claimed in claim 1, wherein the shielding plates are free from an electrical contact or have the same polarity as the carrier outer plates immediately adjacent to the shielding plates.

5. The holding apparatus as claimed in claim 1, wherein each shielding plate comprises a cooling structure.

6. The holding apparatus as claimed in claim 5, wherein the cooling structure is in the form of a rib-like and/or wave-shaped surface structure of each shielding plate.

7. The holding apparatus as claimed in claim 1, wherein the shielding plates are multilayered.

8. The holding apparatus as claimed in claim 1, wherein the shielding plates are made of a base material selected from the group of graphite, carbon fiber-reinforced plastic or carbon fiber-reinforced carbon.

9. The holding apparatus as claimed in claim 8, wherein outer surfaces of the shielding plates are provided with a coating in the form of a metal layer.

10. The holding apparatus as claimed in claim 1, wherein the carrier inner plates and the carrier outer plates comprise cutouts in which the substrates may be accommodated and/or in that the shielding plates are free from cutouts, openings and holes.

11. A method of holding substrates, comprising arranging substrates in the holding apparatus as claimed in claim 1 and performing a plasma-assisted deposition from the gas phase.

12. The holding apparatus as claimed in claim 8, wherein the metal layer is a noble metal layer.
